(19) United States
(12) Patent Application Publication
(10) Pub. No.: US 2008/0053509 A1
(43) Pub. Date: Mar. 6, 2008

(54) Combined thermal diodic and thermoenergy devices and methods for manufacturing same

(76) Inventors: Frederick A. Flitsch, New Windsor, NY (US); Lloyd Wright, Hopewell Junction, NY (US); Lloyd Young, Pleasant Valley, NY (US)

Correspondence Address: Joseph P. Kincart, Esq., 8153 Middle Fork Way, Jacksonville, FL, 32256, US

(21) Appl. No.: 11/700,324

(22) Filed: Jan. 31, 2007

Related U.S. Application Data
(60) Provisional application No. 60/763,731, filed on Jan. 31, 2006.

(51) Int. Cl. H01L 35/28; B05D 5/12; C23F 1/00

(52) U.S. Cl. 136/203; 216/39; 427/123

(57) ABSTRACT

The present invention provides thermoelectric or thermodiodic devices and methods for manufacturing such devices.

### CROSS REFERENCE TO RELATED APPLICATIONS

This application claims priority to Provisional Application No. 60/763,731 filed Jan. 31, 2006 and entitled Thermal Diodic Devices for High Cooling Rate Applications and Methods for Manufacturing Same.” The contents of each are relied upon and incorporated herein by reference.

### FIELD OF THE INVENTION

This invention relates generally to devices with thermoelectric and thermal diodic characteristics. In particular the present invention combines thermoelectric devices with thermal diodes to provide efficient thermal energy transfer devices that may be useful for power generation applications and cooling/heating applications.

### SUMMARY

Thermocouples operating in accordance with the Peltier effect are well known in the arts. Applications for thermoelectric devices include heating, power generation and temperature sensing. However, the efficiency of previously known thermoelectric devices limited their usefulness.

According to Peltier, arranging two dissimilar conductors next to each other and applying a voltage differential across the conductors can create a thermo electric device. Thermoelectric devices, including, for example, Peltier Crystals, may be formed, for example, with two dissimilar semiconductors, such as bismuth telluride (Bi₂Te₃) doped with selenium and antimony (Bi,Sb)₂Te₃ & Bi₂(Te,Se)₃ to form N-type and P-type materials. Other exemplary materials may include PbTe and SiGe.

With a voltage applied across the two types of materials, the electrons in each material have a different potential energy. Therefore to move from one type of material to another type of material, the electrons must either absorb energy or release it, depending upon which direction they travel. Therefore, with a thermoelectric device the application of a voltage can cause thermal energy to be absorbed on one side of the device and released on the other.

The efficiency of a Peltier Crystal thermoelectric device is generally limited to an associated Carnot cycle efficiency reduced by a factor which is dependent upon the thermoelectric figure of merit of materials used in fabrication of the associated thermoelectric elements, ZT, where Z=□²/□□ with □=the Seebeck coefficient (the change in voltage with temperature dV/dT), □=the electrical resistivity, and □=the thermal conductivity. As can be seen from the definition of Z, the efficiency of a thermoelectric device decreases with increasing thermal conductivity or electrical resistivity. Improving the efficiency of thermoelectric devices requires either increasing the Seebeck coefficient or reducing the thermal conductivity or electrical resistivity. According to the present invention, the thermal conductivity is reduced with a thermal diode.

Additionally, in some embodiments, a composite device can include a first portion with more conventional Peltier material and a second portion with TTD material and lower thermal conductivity to form it is also true of the present invention that the temperature gradient across the conventional device is kept as close to 0 as possible; equally reducing the effect of thermal conductivity.

According to some embodiments, a Peltier Crystal can be fashioned by extruding a billet of P-type material to form a P-type extrusion, also extruding a billet of N-type material to form an N-type extrusion. The P and N-type extrusions can be sliced into wafers; the wafers can be sliced into small elements. The elements can be mechanically loaded, for example, into a matrix of a desired pattern and assembled upon an electrically insulating plate with small copper pads connecting elements electrically in series and thermally in parallel on the plate.

Other embodiments can include forming a thermoelectric material by combining a P-type extrusion with a N-type extrusion to form a P/N-type billet. The P/N-type billet may be extruded to form a P/N-type extrusion having P-type regions, and N-type regions. According to these embodiments, the number of P-type regions and N-type regions can correspond with the number of P-type extrusions and N-type extrusions used to form the P/N-type billet.

Some embodiments can also include a thermoelectric module with two ceramic substrate plates that serve as a foundation and also as electrical insulation for P-type and N-type Bismuth Telluride blocks. A pattern of blocks can be laid out on the ceramic substrates so that they are electrically connected in series configuration. The position of the blocks between the two ceramic substrates can provide a parallel configuration for the thermal characteristics of the blocks. The ceramic plates can also serve as insulation between a) the blocks internal electrical elements and a thermal energy sink that will typically be placed in contact with the hot side and b) the blocks internal electrical elements and whatever may be in contact with the cold side area.

Embodiments can include modules with an even number of P-type and N-type blocks. The blocks are arranged, for example, so that one of each type of block shares an electrical interconnection often referred to as a “couple.”

As discussed above, it is known for P-type to be fashioned from an alloy of Bismuth and the N-type to be fashioned from an alloy of Tellurium. Both Bismuth and Tellurium have different free electron densities at the same temperature. P-type blocks are composed of material having a deficiency of electrons while N-type has an excess of electrons. As current flows through the module (up and down through the blocks) the amperage attempts to establish equilibrium throughout the module. The current causes the P-type material to become analogous to a hot area that will be cooled and the N-type to become analogous to a cool area that will be heated. Since both materials are actually at the same temperature, the result of the applied current is that the hot side of the module is heated and the cold side of the module is cooled. Since direct current is applied, the direction of the current can be used to determine whether a particular side of the module will be cooled or heated. Simple reversal of the DC polarity will switch the hot and cold sides.

Various features and embodiments are further described in the following figures, drawings and claims.

### DESCRIPTION OF THE DRAWINGS

FIG. 1 illustrates a block diagram of some embodiments of the present invention comprising a combination of a thermoelectric device and a thermal diode.

FIG. 2 illustrates a block diagram of some embodiments of the present invention comprising a layered combination including a thermal diode bordered by a thermoelectric device on two areas.

FIG. 3 illustrates a block diagram of some embodiments of the present invention comprising a layered combination including multiple thermal diodes bordered combined with thermoelectric devices.

FIGS. 4A & 4B illustrate exemplary basic thermal diodic device with aspects of the present invention.

FIGS. 5A & 5B illustrate some exemplary embodiments of thermal diodic aspects of the present invention.

FIGS. 6A & 6B illustrate additional exemplary embodiments of thermal diodic aspects of the present invention.

FIG. 7 illustrates some exemplary embodiments of the present invention comprising Peltier crystals.

FIG. 8 illustrates some exemplary embodiments of the present invention comprising thermal diode portions and thermoelectric portions with varying surface areas.

FIG. 9 illustrates some exemplary embodiments which include multiple thermal diodic portions.

FIG. 10 illustrates some exemplary embodiments of the present invention comprising at least one thermoelectric device portion, at least one thermal diode portion and at least one thermal energy sink portion.

### DETAILED DESCRIPTION

Overview

The present invention provides devices which combine thermoelectric devices with thermal diodes thereby providing an efficient means of transferring thermal energy from a first area to a second area. As referred to herein, a thermoelectric device includes any device that can respond to the application of a DC voltage by transferring thermal energy from a first portion to a second portion, a Peltier Crystal includes a thermoelectric device with dissimilar materials that is capable of controllably transferring thermal energy from one portion of the device to another portion of the device or alternatively, creating a voltage when a temperature differential is applied across the dissimilar portions. A thermal diode includes a diodic device capable of controllably transferring thermal energy in one direction from one portion of the diodic device to another portion of the diodic device and to resist the transfer of thermal energy in the opposing direction.

As presented herein, various embodiments of the present invention will be described followed by some specific examples of various components of the devices presented herein and examples of how the various components may be combined.

Thermal Energy Devices

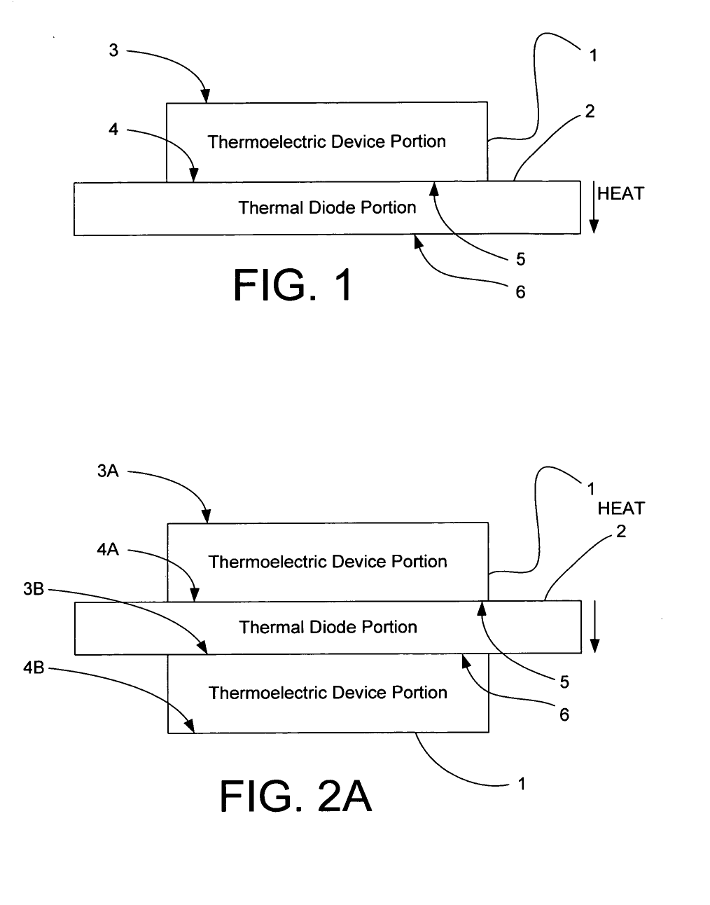

Referring now to FIG. 1, a block diagram of a device according to some embodiments of the present invention illustrates a device with a thermoelectric device portion 1 and a thermodiodic portion 2.

According to the present invention, the thermoelectric device portion 1 which is capable of conducting thermal energy from a first area 3, to a second area 4 with the application of a direct current (DC) voltage across the thermoelectric device 1, is fashioned adjacent to a thermal diode portion 2. Inherent in the thermoelectric device 1 can be a tendency to have thermal conductivity transfer thermal energy back across the device from the second area 4 to the first area 3. However, with the application of a DC voltage across the thermal diode 2, the thermal diode 2 will conduct thermal energy away from a first area of the thermal diode 5 to a second area of the thermal diode 6 with little or no thermal conductivity from the second area of the thermal diode 6 back to the first area of the thermal diode 5.

Embodiments of the present invention are therefore capable of transferring thermal energy away from the second area of the thermoelectric device 4. With thermal energy being transferred away from the second area of the thermoelectric device 4, the temperature differential between the first area of the thermoelectric device 3 and the second area of the thermoelectric device 4 is decreased resulting in less thermal energy being conducted back across the thermoelectric device from the second area 4 to the first area 3.

Devices according to the present invention therefore provide more efficient thermal energy transfer from a first side of the device 3 to a second side of the device 6.

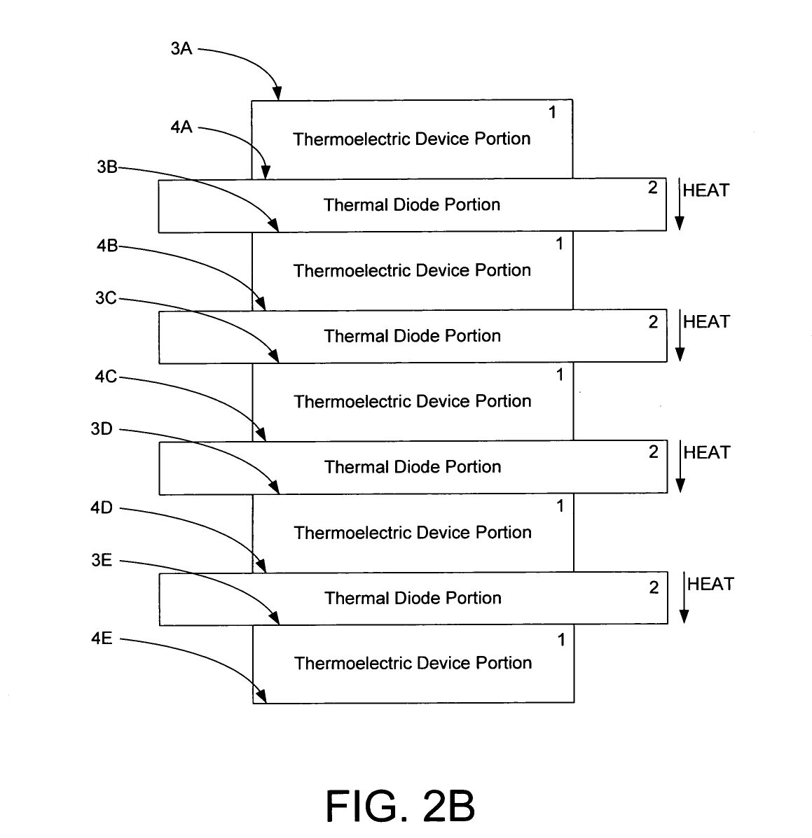

Referring now to FIG. 2A, in some embodiments of the present invention, one or more layers of thermoelectric devices 1 and thermal diodes 2 can be combined to increase the power generation capacity or increase the efficiency to transfer thermal energy, according to a particular application. Multiple layers 3A-3E to 4A-4E of thermal diodes 2 and thermoelectric portions 1 can also be arranged in thermal and electrical series, for example as illustrated in FIG. 2B, and the temperature differential can be controlled across any particular thermal diode portion 2. Control of the temperature differential can be useful, for example, to limit any adverse physical effects, such as expansion or contraction that may cause cracking between layers that would otherwise have larger temperature differential.

The thermal energy differential of a particular thermal diode portion 2, can be controlled by controlling a voltage applied across the particular diode 2, when individual diode control is afforded, or by the aggregate voltage across the entire stack of thermal diodes in an application for transferring thermal energy.

Thermal Diodic Portions and Methods of Manufacture

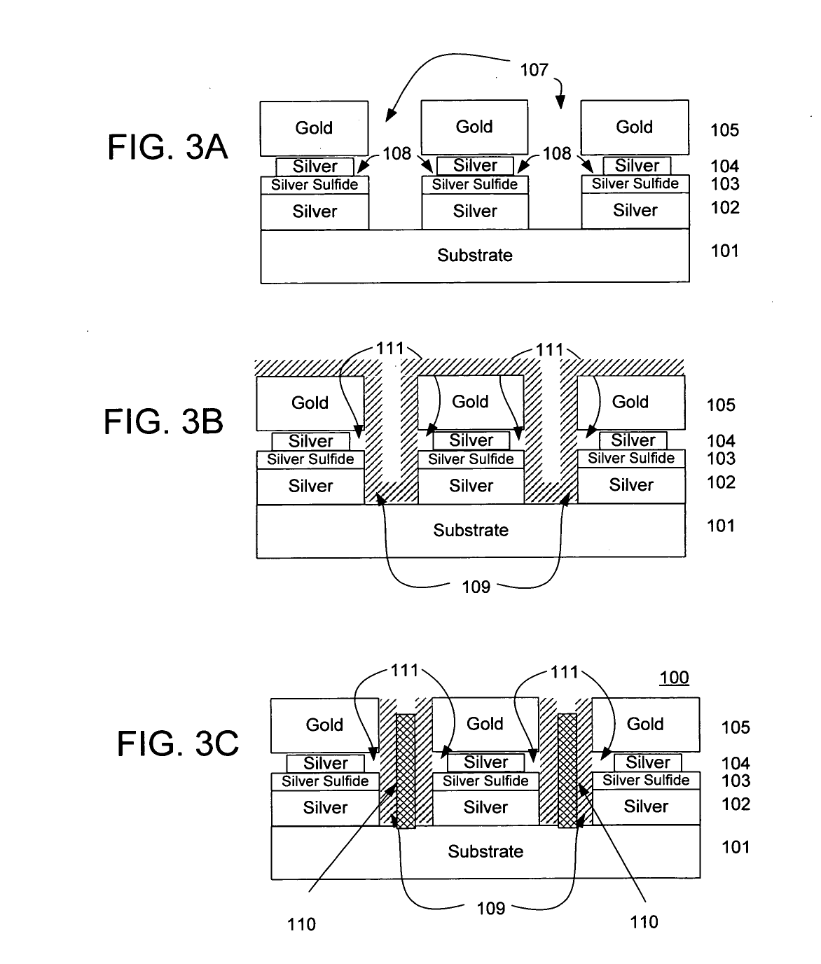

Referring now to FIG. 3A, a block diagram depicting some devices according to the present invention and method steps that can be used to fashion devices according to some embodiments of the present invention are illustrated. A metallic layer, such as, for example, a layer of Ag 102 can be applied to a metallic or metallic coated substrate 101. The metallic or metallic coated substrate 101 can include, for example, flat quartz with an Au coating or a planarized copper substrate.

In some exemplary embodiments, thickness of the metallic coated substrate 101 can include a substrate greater than, or approximately equal to 100 microns. Generally, embodiments can include any metallic or metallic coated substrate comprising sufficient electrical, mechanical and thermal characteristics. The layer of Ag 102 can be deposited on the metallic coated substrate 101, for example via sputter deposition or plating. In other embodiments, an Au plate can take the place of the metallic coated substrate with an Au coating.

The Ag layer 102 can be reacted to form a conductive ionic layer 103, such as for example, silver sulfide (AgS). The ionic conductive layer 103 can be formed, for example by reacting the Ag 102 in a sulfide inducing environment, such as, for example, exposure to H₂S at 80° C. In some embodiments, the thickness of the AgS layer 103 may be self limiting by the environment in which it is created. Some embodiments may include an AgS layer 103 of 80 Ang to 120 Ang.

A second metallic layer 104, such as a second layer of Ag 104 can be applied on top of the conductive ionic layer 103, such as, the layer of Ag₂S layer 103. The second metallic layer 104 can be applied by any method known in the arts. In some embodiments, for example, the second layer of Ag 104 can be deposited via sputtering or applied via evaporator plating.

For generality, it should be apparent to those skilled in the arts that the combinate of 102, 103 and 104, which has been described as Ag, Ag₂S, and Ag, can be formed by an equivalent combination of layers that would constitute a layer formation with an ionic conductor in the middle. Said middle layer, 103, can be chemically formed, as was the case with Ag₂S, or it can be separately deposited.

A third metallic layer 105, different than the second metallic layer 104 can also be deposited. In some embodiments, the third metallic layer 105 can include gold (Au). The Au layer 105 can be deposited by any known means, such as, for example, via sputter or evaporator plating.

Although this embodiment would describe layer 105, as different from the constituents of layer 104, for generality it should be noted that the presence of an interface layer between like metal layers 104 and 105 (if 104 and 105 were the same metals) can provide a sufficient formation for the device processing flow described in this invention.

After the Au layer 105 has been applied, portions of the applied layers 102-105 can be selectively removed. At 1E, a photoresist pattern can be applied as a photoresist mask 106 on top of the layer of Au 105. The pattern can be applied by any known method in the arts. In some preferred embodiments, the pattern will include the basis of at least one discrete device and in some embodiments, the basis of multiple discrete devices. In some embodiments, discrete devices can be fashioned in a shape which corresponds with the physical characteristics of a particular application. For example, some embodiments can include a photoresist pattern with multiple shapes, each shape corresponding with the physical dimensions of a computer chip that the thermal diodic discrete device will be utilized to cool, other shapes may include circular or semi-circular shapes, octagons, pentagons, rectangles or any other desired shape. For the purposes of this description, a simple rectangle will continue to be described, however, this is not meant to limit the scope of the invention.

In some preferred embodiments, the photoresist mask will define multiple discrete devices. A gap 107, can separate each device. For example, the gap 107 may be between 1,000 Ang to 10,000 Ang, but in general, the gap is only limited by the physical dimensions of the materials being used, such as, for example, the physical size of the metallic substrate 101, the design of the pattern and the number of devices defined.

Etching can be used to remove portions of the third metallic layer 105 left exposed by the photoresist mask 106. In the example illustrated, the third metallic layer 105 includes Au. Etching can be accomplished using any method known in the art, such as, for example, reactive ion etching or sputter/physical bombardment etching. In some embodiments, anisotropic etching can be utilized to etch one or more layers 102-105 in a pattern closely defined to the pattern defined by the photoresist mask 106. In other, less preferred, embodiments the etching can be performed by isotropic chemical etching techniques.

Etching can be additionally used to remove portions of layer 104 based on the pattern of the photomask. In the preferred embodiment shown, a recess in the shape of the feature formed by etching of layer 104 can be formed by use of an isotropic chemical etching process. Such processing would result in a recess of the profile of the gap 107 at all edges of the remaining feature from layer 104. This recess is indicated as 108. Etching can be additionally used to remove defined portions of one or more of: the second metallic layer 104, the conductive ionic layer 103, and the first metallic layer 102. Accordingly, in some embodiments, anisotropic etching can be continued resulting in essentially a uniform cut through all of the layers 102-105 until the metallic coated substrate 101 is reached.

In some other embodiments, isotropic etching can be used to remove portions of one or more of: the second metallic layer 104; the conductive ionic layer 103; and the first metallic layer 102; thereby defining an undercut region 108 beneath the third metallic layer 105. Therefore, following the examples above, some embodiments can include use of an etching technique, such as selective wet chemistry etching, to remove portions of the second layer of silver 104, the silver sulfide 103 and the first layer of silver 102 underneath layer of gold 105, thereby creating an optional undercut 108 under the gold 105.

In addition, it should be understood that embodiments can include undercut regions 108 or not include the undercut regions 108.

Referring now again to FIG. 3A, following the etching steps, the photo resist pattern 106 is removed. In some embodiments, such removal may be performed by a standard chemical processes used in the art to strip photoresist or a chemical plasma etching tool, typically referred to as an asher. Additional processing, such as, for example, additional wet cleaning processing, can result in a clean structure including primarily the materials of layers 101-105.

At 3B an insulator 109 can be applied into the etched out areas 107. In some embodiments, in which the etching created an undercut 108 under the gold 105, the insulator layer 109 can be applied into the etched out areas 107, but leave a void 111 in the undercut region. Other embodiments can include the insulator 109 filling the undercut region 108. In still other embodiments, no undercut region 108 will be formed by the etching and the insulator layer 109 only fills the etched out areas 107.

In some other embodiments, the undercut region 108 can be evacuated and encapsulated with deposited insulator layers. A common deposition process for insulators, PECVD, can carry out this effect since the process is inherently a vacuum based process. Therefore, the ambient in the encapsulated void region, 111, reflects the pressure in the deposition process and any gas materials present in that deposition ambient. For example, in some embodiments, the undercut region 108 can be filled with nitrogen and sealed in with an insulator layer 109 such as Silicon Oxide. In other embodiments, the undercut region 108 can contain other gasses. In the preferred embodiment, the nature of the ambient of the undercut region 108, may be less critical than for other embodiments, where the undercut 108 occurs along all layers 102-104.

The layer thickness of insulator layer 109 can be made thick enough to entirely fill the gap 107. However in the preferred embodiment, its thickness would be less than that to fill the gap. Such a strategy can allow for the gap to be completed with a material composition that would have lower thermal transfer capabilities than the material of the insulator 109, since such thermal transfer would be a parasitic aspect of the device thus formed. Nevertheless, the layer formed in etched out areas 107, can be formed in such a manner to ensure mechanical rigidness of the formed layer structure. It can also provide significant sealing ability of the layer structure from the ambient.

At 3B, a PECVD process used to form layer 109 would result in deposition filling along the sides of the gap 107 as well as at the bottom of the gap 107. Furthermore, the top metal structure 105, would also be coated with the deposited insulator 109 as illustrated. In some embodiments this coating 109 can be removed with an etching step that would etch the flat surfaces of the insulator 109-110, and, in some embodiments, also etch the tops of metal structures 105 and the bottom of the gaps 107, leaving vertical structure along the sidewall of the gap 107.

In some embodiments, including a preferred embodiment, an additional layer of insulator 110 can include a low density oxide or a low thermal conducting material. For example, a layer of low density SiO₂ can be processed by spinning the material onto the substrate. Such a spin on glass (SOG) material would fill the portion of the gap 107 that was not filled in initially with the insulator 109. This SOG would preferentially fill this gap, but can end up with some additional deposit on top of the gold. An etching process, either dry or wet can once again be used to remove the insulator from the top of the Au layer 105. Alternatively, if the initial insulator layer 109 was not etched as described above, some embodiments can include composite insulator layers 109 and 110 being etched by reactive ion etching. Embodiments can therefore result in a structure 100 that is generally equivalent to that shown in FIG. 3C.

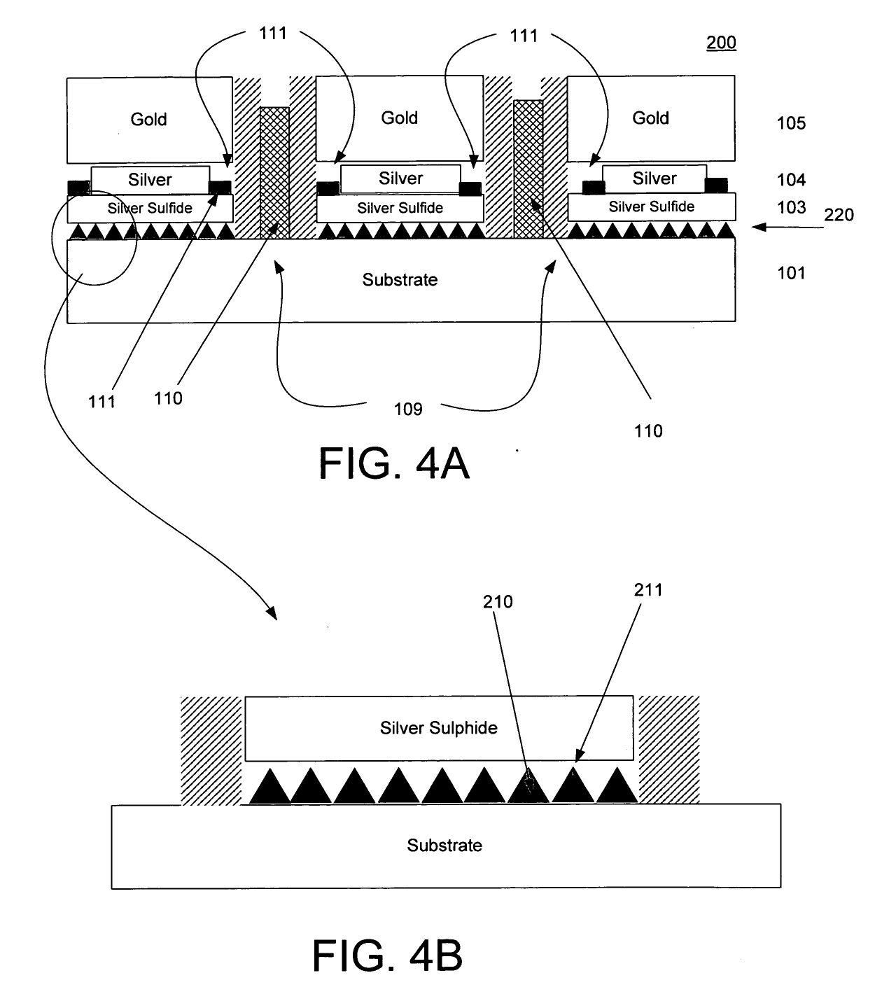

Referring now to FIGS. 4A and 4B, after the device structure 200 has been thus formed, the structure 200 can be further processed by applying an electrical current by various means across the layers from the gold 105 to the substrate 101. In devices of the types that include an ionic conductor layer in them, as shown in the preferred embodiment as layer 103, an electrical current can be passed through the ionic conductive layer 103 to cause two forms of electrical motion occur. Electrons can flow from one side of the device to the other, for reference we will consider the case where electrons flow from Au 105 to the substrate 101. In such embodiments, there will also be a contribution to the current that comes from the motion of positively charged silver ions inside the ionic conductor 103 in a direction opposite to the electron flow. Such a flow will result in silver atoms being depleted from the interface of layer 103 with layer 102.

In FIG. 4A, the effect of the current applied from the Au 105 to the substrate 101 on the overall device 101-105, 109-111 of these types, is generally illustrated. As can be seen, the Ag layer 102 has been has been physically altered into a new layer indicated as layer 220.

Referring now to the close up diagram shown in FIG. 4B, a rough surface topography that would result from the atomic movement is generally illustrated and indicates “Spike like” features 210 which are formed from the silver material and also a gap, shown as 211. The gap 211 is formed as a result of silver atoms that move under the influence of the field across the device 200 until a last silver atom moves and there is no longer a solid connection across the Au layer 102.

With the formation of a gap 220 in the silver layer 102, the structure of the device 200 in other ways remains the same. The Au 105 and the AgS layer 103 continue to be held in place by the other layers of the resulting device, such as, for example, the layers of insulator 109 and SOG 110. In addition, with the layer of Ag 102 removed, the resulting gap 211 acts as a thermal insulator.

In some embodiments, solid state conduction of electrons across the Ag layer 102 ceases with the formation of the gap 211. Any current which flows with the gap 211 comes from different forms of conduction, such as, for example, tunneling of electrons across the gap 211. This structure 200 provides a desired form which enables control of thermionic effects across the gap 211 and also has insulating properties due to the gap 211. Some embodiments of the present invention can include further processing of the environment of the gap 211, however FIG. 4 shows some embodiments of a device according to the concepts of this invention which includes the desired thermal diodic behavior.

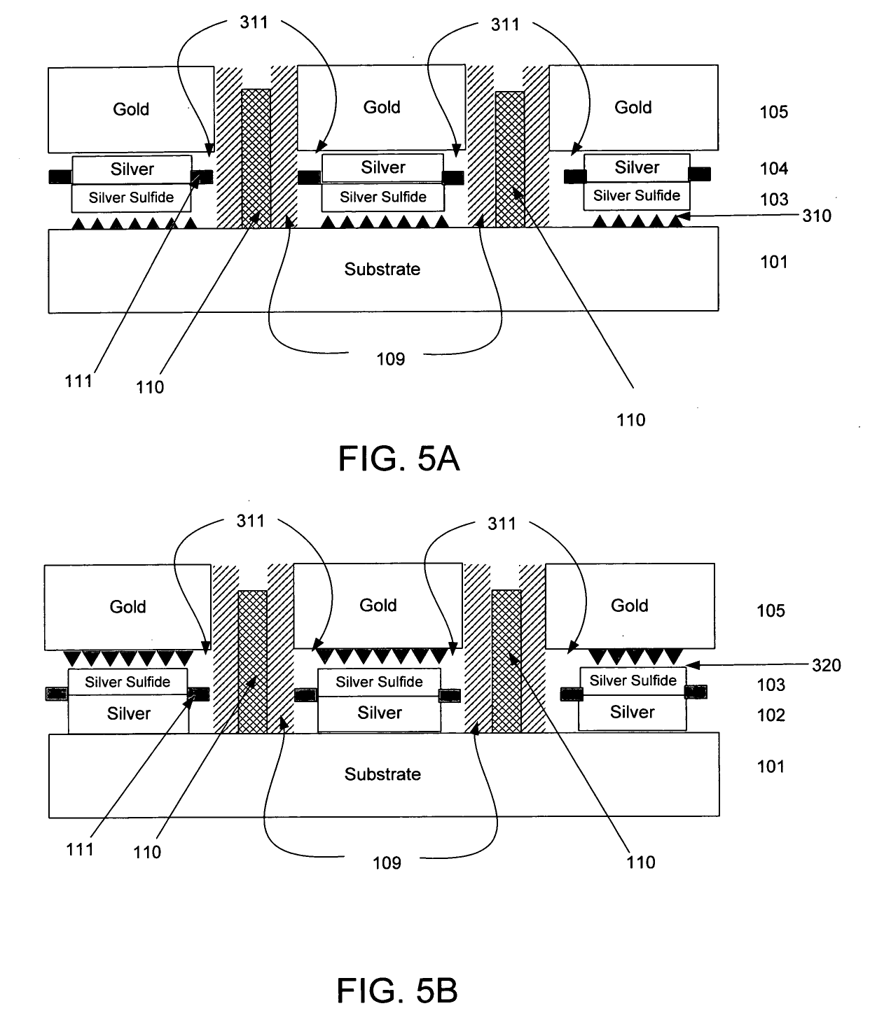

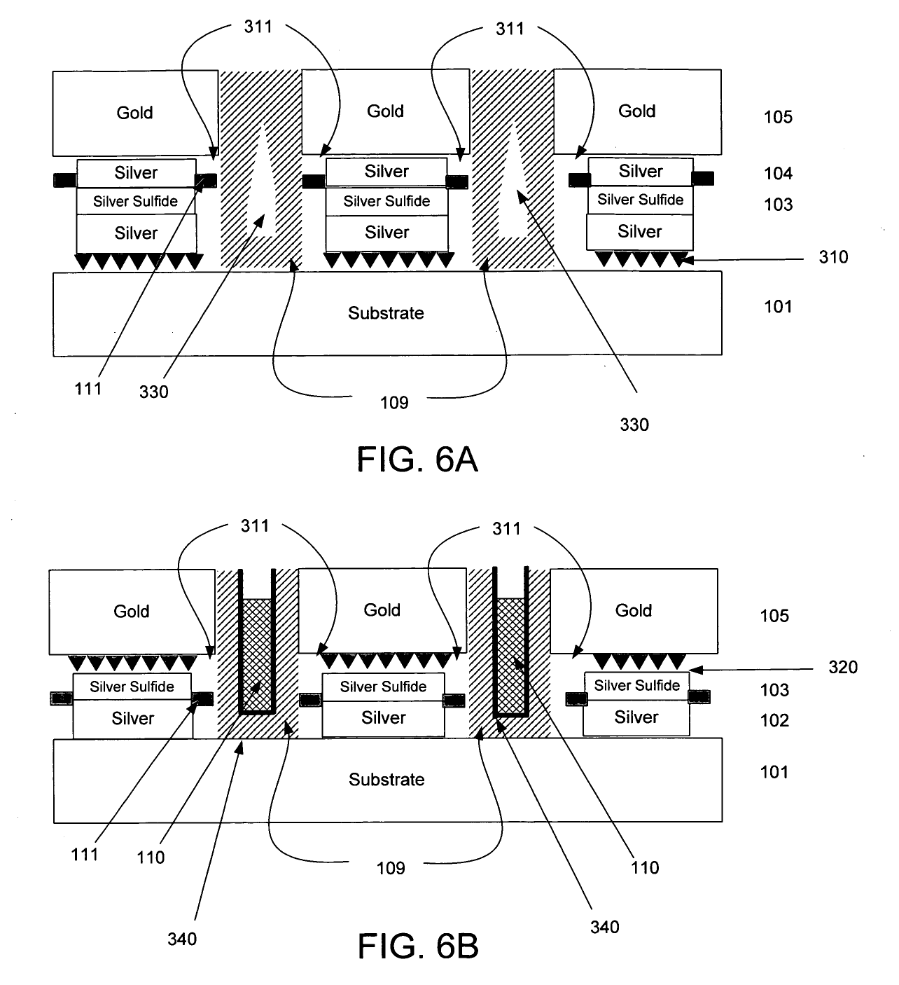

FIG. 5A, illustrate exemplary embodiments where the electron flow is from 105 towards 101. Furthermore, FIG. 5B illustrates exemplary embodiments with an analogous structure that is formed as a result of electron flow directed from 101 towards 105. An alternative embodiment of the same basic structure is shown in FIG. 6A.

In another aspect, the above embodiments can additionally include a PECVD step to form item 109 which is performed in a manner that it will “neck off” at the top forming void 330. In these embodiments, the gap 310-311, in the shape of a channel, would be filled with a vacuum space and have low thermal conductivity.

Referring now to FIG. 6B, the presence of a vacuum in the region of the created gap, 320, can be important to various embodiments of the device type. In addition, the presence of an insulator 109 comprising PECVD film can form the environment of the gap 320 and undercut region 308 in a low vacuum state. However, in some embodiments, further processing of the device 3B may allow for molecules to penetrate the PECVD film 109 thereby subverting the vacuum state of the gap 310, 320 and the undercut 308. In some embodiments, therefore, a metallic film 340 can be applied by deposition on the outside of the PECVD insulator film 109. The metallic film 340 seals the created gap 320 from molecules that may otherwise penetrate the PECVD film.

A further refinement of the device type (not illustrated) can include an access via that is cut into the Au 105. Said access via can be formed by another photomask step that allows a reactive ion etch process to etch a hole into the Au 105. The depth of the access via can be at least as deep as the sulfide layer 103. Such a via hole can allow for access to the formed gap region for various purposes. In some embodiments, the purposes can include evacuation of the gap region and also chemical and gaseous treatment of the surfaces inside the region of various types. It should be noted that the access via feature has been described in relation to these embodiments, but it should be apparent that a via can as well be more generally applied to various embodiments.

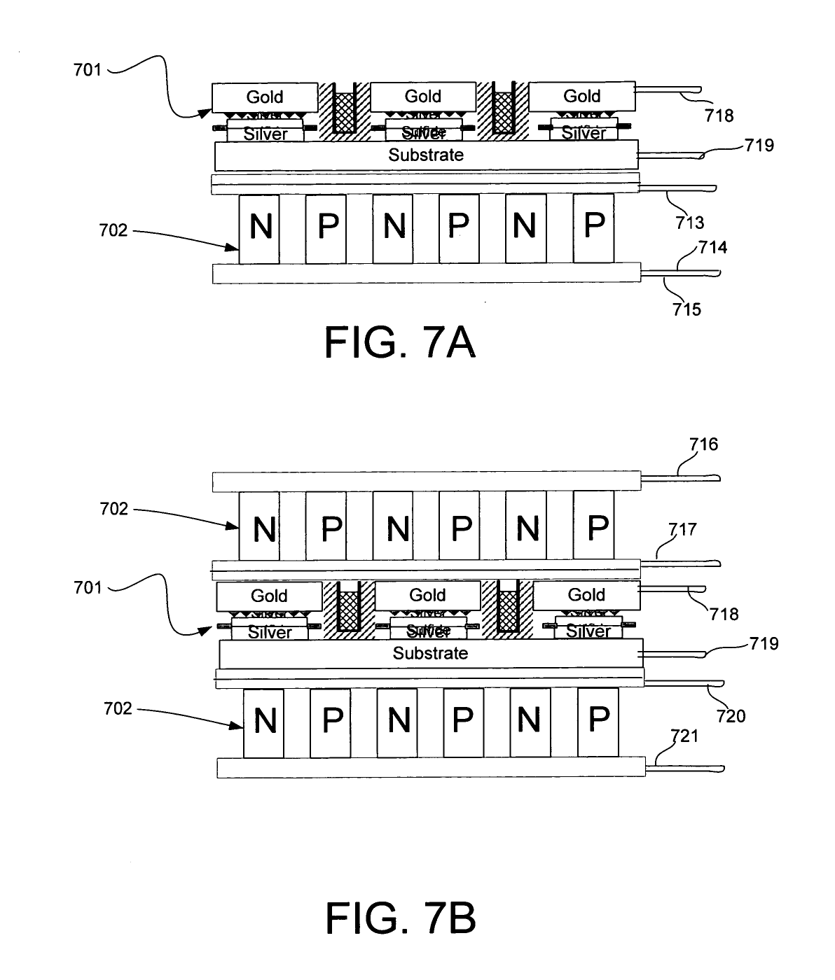

Referring now to FIGS. 7A and 7B, according to some embodiments of the present invention, Peltier crystal arrays including elements of N-type material 501,503 and elements of P-type material 502, 504 are combined with the thermal diodic devices described above.

At 7A, a thermal diodic device 701 can be arranged between the Peltier crystals of N-type elements 501, 503 and P-type elements 502, 504 and conductive plates 521-524 arranged on an electrically insulating substrate block 510. The N-type blocks 501, 503 and P-type blocks 502, 504 can be electrically connected in series and thermally connected in parallel with the conductive plates. In some embodiments, conductive substrate layers 531-538 can be included on either side of the layers of micro sized units 511-514 with the ionic conductor layers 515-518.

Various embodiments can also include additional layers according to desired characteristics of a device, such as, for example a thermal diode characteristic. For example, at 7B, one or more layers of thermal diodic devices 701 can be sandwiched in between the Peltier crystals of N-type elements 501A, 501B and 503A, 503B and P-type elements 502A, 502B and 504A, 504B.

The one or more layers of thermal diodic devices 701 fashioned in series with the N-type and P-type elements can act as a thermal diode and block the thermal conduction from a hot side to a cold side of a module that includes both the N-type and P-type elements and the one or more of thermal diodic devices 701. In this arrangement, the current that flows through the N-type and P-type elements will also flow through the one or more layers of thermal diodic devices 701 and cause the one or more layers of thermal diodic devices 701 to also act as a heat pump. The thermal diodic devices 701 will also act to prevent thermal conduction of thermal energy back through the of thermal diodic devices 701.

Peltier Crystals

To form the elements of N-type material 501, 503 and elements of P-type material 502, 504, billets of N-type material can be extruded to form an N-type extrusion and billets of P-type material can be extruded to form a P-type extrusion. The N and P-type extrusions can each sliced into wafers, the wafers are sliced into small elements, and the elements are mechanically loaded into a matrix of a desired pattern and assembled upon an electrically insulating plate 507 with small copper pads 509-510 connecting the N-type elements and the P-type elements electrically in series and thermally in parallel on the plate 507.

In other embodiments, a N-type extrusion and a P-type extrusion can be combined to form a N/P-type billet. The N/P-type billet (not shown) may be extruded to form a N/P-type extrusion having N-type regions, and P-type regions. According to these embodiments, the number of N-type regions and P-type regions can correspond with the number of N-type extrusions 501, 503 and P-type extrusions 502,504 used to form the N/P-type billet.

In some embodiments that include N-type and P-type elements and at least one layer of micro sized units with an ionic conductor layer, the P-type material can be fashioned from an alloy of Bismuth and the N-type can be fashioned from an alloy of Tellurium. Both Bismuth and Tellurium have different free electron densities at the same temperature. P-type blocks can include a material having a deficiency of electrons while N-type can have an excess of electrons.

As current flows through a module of N-type and P-type elements (up and down through the elements) the amperage attempts to establish equilibrium throughout the N-type and P-type elements. The current causes the P-type material to become analogous to a hot area that will be cooled and the N-type to become analogous to a cool area that will be heated. Since both materials are actually at the same temperature, the result of the applied current is that the hot side of the module is heated and the cold side of the module is cooled. Application of direct current (DC) can be used to determine whether a particular side of the module will be cooled or heated. Reversal of the DC polarity can be used to switch the hot and cold sides.

Some embodiments can include a Peltier Crystal that includes a tunneling-effect converter of thermal energy to electricity with an emitter and a collector separated from each other by a distance that is comparable to atomic dimensions and where tunneling effect plays an important role in the charge movement from the emitter to the collector across the gap separating such emitter and collector. At least one of the emitter and collector structures includes a flexible structure. Tunneling-effect converters include devices that convert thermal energy to electrical energy and devices that provide refrigeration when electric power is supplied to such devices.

Still other embodiments can include one or more Peltier Crystal portions with a tunneling-effect converter, that includes: an electric charge collector having a collector surface, wherein said collector surface is atomically smooth; an electric charge emitter having an emitter surface, wherein said emitter surface is atomically smooth and wherein said emitter surface is separated from said collector surface by a gap such that said emitter surface is separated from said collector surface by a distance that is less than or equal to about 5 nm; and a spacer between said collector and said emitter, wherein said spacer includes dielectric material in contact with said collector surface and with said emitter surface.

Some embodiments can also include one or more Peltier Crystal portions with a tunneling-effect converter that includes: an electric charge collector having a collector surface; an electric charge emitter having an emitter surface, wherein the collector surface is separated from said emitter surface by a distance such that the probability for electron tunneling between said emitter surface and the collector surface is at least 0.1%; and a spacer between said collector and the emitter, wherein said spacer can include a dielectric material in contact with said collector surface and with said emitter surface.

Still other embodiments can include one or more Peltier Crystal portions with a tunneling-effect converter, that includes: an electric charge collector having a collector surface; an electric charge emitter having an emitter surface, wherein at least one of the collector and the emitter comprises an electrically conductive flexible layer; and a spacer between said collector and the emitter, wherein the spacer comprises dielectric material in contact with the collector surface and the emitter surface, and wherein the emitter surface is separated from the collector surface by a distance that is less than or equal to 5 nm.

Some embodiments can also include one or more Peltier Crystal portions with a tunneling-effect converter that includes: an electric charge collector having a collector surface that is atomically smooth; an electric charge emitter having an emitter surface that is atomically smooth, wherein at least one of said collector and the emitter is a flexible electrode; a spacer between the collector and said emitter, wherein the spacer includes dielectric material in contact with the collector surface and the emitter surface; and a means for load distribution applied to said flexible electrode.

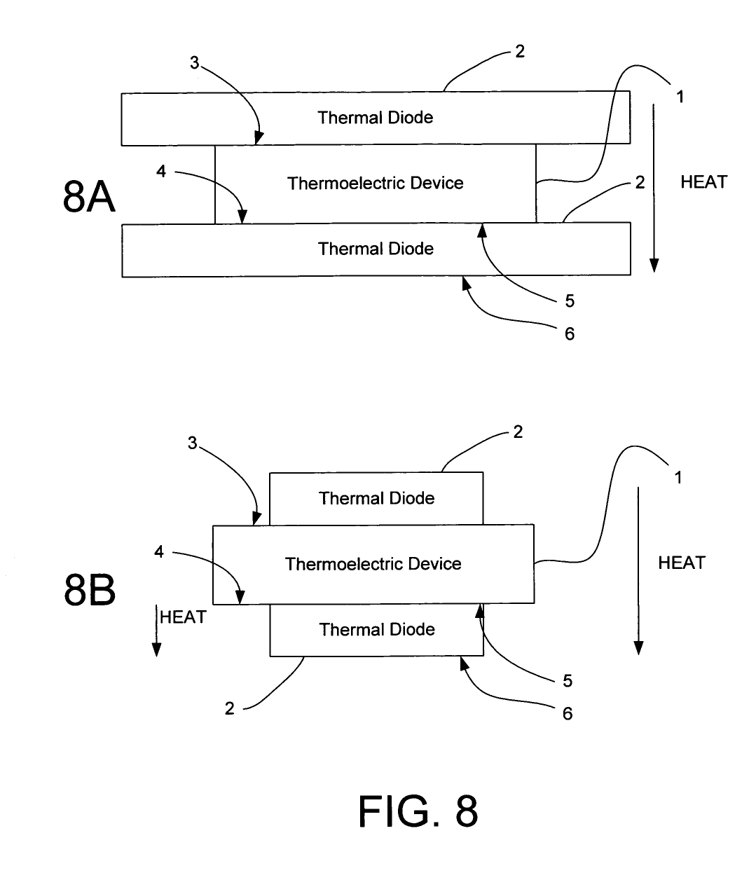

Referring now to FIG. 7, those schooled in the arts will also understand that the separate leads in FIG. 7 shown as items 711-721 are exemplary of the fact that the individual stacked components can be made to be individually connected to electrical power supplies and therefore adjusted for consistency between the diodic layer(s) and the thermoelectric layer(s). It should be obvious that by connecting any adjacent pairs of the electrical leads, for example 712, 713 that the composite device can be made to conduct the electrical current in a series manner. In such a connection, it is possible that the series current would yield different cooling rates for the two device types which could be an inconsistent mode of operation. FIG. 8 demonstrates the concept that could be applied to scale the device area in those composite devices where the current is driven in series through all components of the composite device.

Referring now to FIG. 8, some embodiments are illustrated which demonstrate that one or more thermal diode portions can be matched with a thermoelectric portion with different surface area characteristics. For example, in FIG. 8A, two thermal diode portions 2 are situated on either side of a thermoelectric portion 1 and each of the thermal diode portions 2 have a greater surface area than the thermoelectric portion 1. In FIG. 8B, two thermal diode portions 2 are situated on either side of a thermoelectric portion 1 and each of the thermal diode portions 2 has a surface area less than the surface area of the thermoelectric portion 1. Some embodiments can include thermal diode portions and thermoelectric portions which have relative sizes such that when a given current is applied across the portions in aggregate, thermal energy is transferred across each of the portions at relative rate and in a predetermined direction.

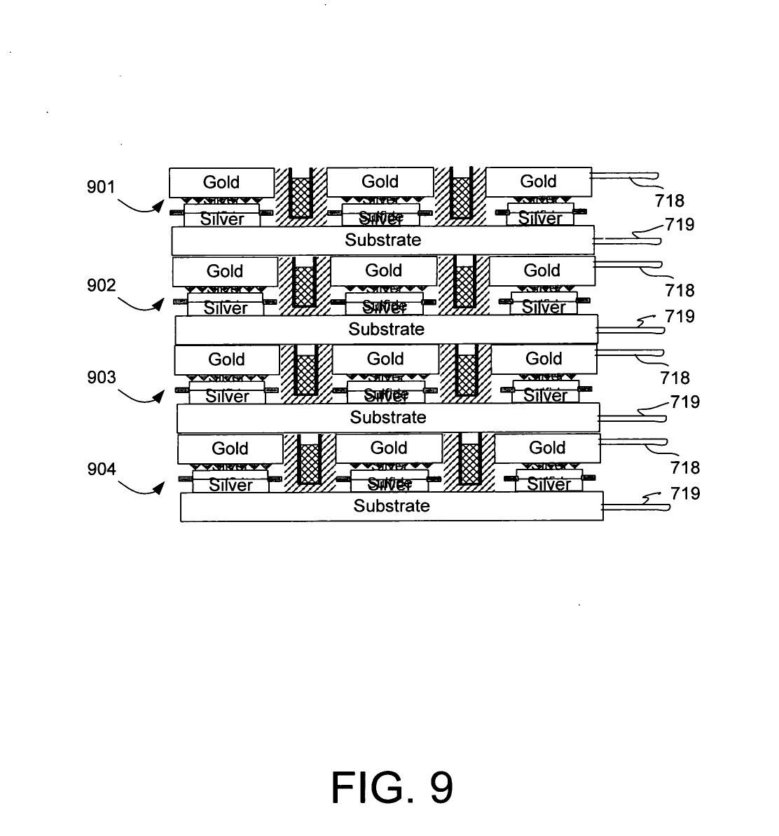

Referring now to FIG. 9, in some embodiments, multiple thermal diodic layers 901-904 can be layered or stacked and in some embodiments, the transfer of energy across each layer can be controlled individually, while in other embodiments the transfer of energy across each layer 901-904 can be controlled in the aggregate. The transfer of thermal energy across each thermal diodic layer 901-904 can be controlled through the application of a DC current across leads 718-719 connected to each layer 901-904. In some embodiments, each layer 901-904 can be a discrete device fashioned, for example, according to the methods presented above and then stacked against each other. Alternatively, some embodiments can include a single device fashioned, for example, through repetition of the methods presented herein. Layered embodiments can be useful for example to limit the thermal differential across any given layer and to also provide greater control over the transfer of thermal energy across the device.

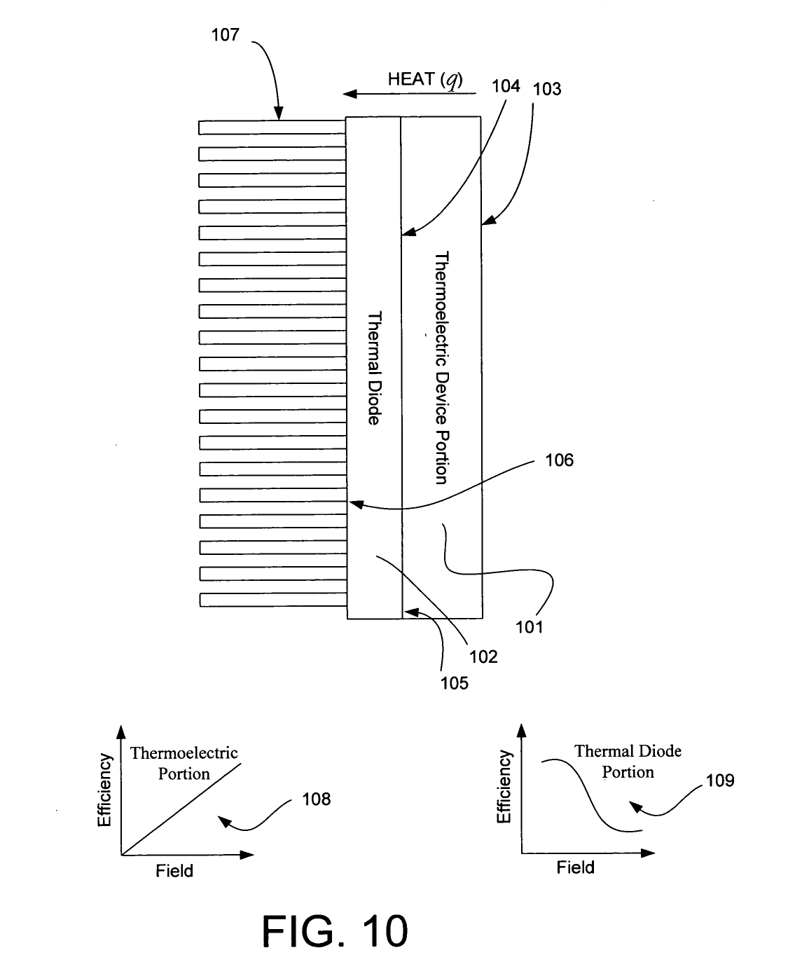

Referring now to FIG. 10, one exemplary application is illustrated showing how a current can be applied across a thermoelectric portion 101 to transfer thermal energy in the form of heat (q) from a first surface 103 to a second surface 104. A current can also be applied across a thermal diode portion 102 to transfer thermal energy from a third surface 105 which is in thermal contact with the surface 104, to a fourth surface 106. In various embodiments, the currents across the thermoelectric portions and the thermal diode portions may be the same current, or individually applied currents. The fourth surface 106 can also be thermal contact with a thermal energy sink 107, such as, for example, fins for cooling by ambient air, or liquid cooling.

In some embodiments, the current applied across the thermoelectric portion 101 and the thermal diode portion 102 can be individually controlled according to the relative ability of each portion to transfer thermal energy and the amount of thermal energy that needs to be transferred. For example, some embodiments may include a thermoelectric portion 101 for which the relationship between the field created by the current applied across the thermoelectric portion 101 and the efficiency of the thermal energy transfer is essentially linear 108. In addition, some embodiments may include a thermal diode portion 102 for which the efficiency of thermal energy transfer may decrease once a threshold current is reached 109.

Some embodiments can therefore include individually adjusting the current across the various portions to obtain a desired result. For example, a current may be applied across the thermal diode portion 102 to create a thermal transfer, however, if the demand for thermal energy transfer increases in a transient fashion to the point where the current that needs to be applied across the thermal diode 102 pushes the thermal diode 102 into a less efficient range, then a current may also be applied across the thermoelectric portion 101 to provide additional thermal energy transfer at a more efficient rate. Essentially, in such embodiments, the thermoelectric portion 101 is switched on if the area sought to be kept cool temporarily gets too hot. It should be noted that in such an operational mode the temperature delta across the thermoelectric device portion would necessarily increase during the course of the transient heat load. This trade off would be operatant in applications where the temperature control of the cool side is the important factor.

Some embodiments can also include using the thermal diode 102 to keep the temperature gradient across the thermoelectric portion 101 at a desired delta, such as, for example: with the thermal energy sink side lower than the thermal energy source side; with the thermal energy sink side essentially the same as the thermal energy source side; the thermal energy sink side hotter than the thermal energy source side; or multiple layers of thermoelectric 101 portions and thermal diode portions 102, with a maximum delta in thermal energy across any given layer. Those skilled in the art will therefore understand that numerous embodiments are included in the present invention with many combinations and applications and many embodiments including various currents applied across layers of thermoelectric 101 and thermal diode 102 portions.

A number of embodiments of the present invention have been described. Nevertheless, it will be understood that various modifications may be made without departing from the spirit and scope of the invention. For example, various methods or equipment may be used to implement the steps described herein. In addition, various casings and packaging can also be included in order to better adapt a thermoelectric or thermodiodic device according to a specific application. Accordingly, other embodiments are within the scope of the following claims.

What is claimed is:

1. A device with a first surface and a second surface comprising thermo diodic characteristics between said first surface and said second surface, and further comprising:
a substrate with a metallic surface;
a first metallic layer comprising a different metal than the metallic surface of the substrate, said first metallic layer in electrical contact with the metallic surface of the substrate;
an conductive ionic layer in electrical contact with the first metallic layer;
a second metallic layer with the conductive ionic layer; and
a third metallic layer, said third metallic layer in electrical contact with the second metallic layer.

2. A device with a first surface and a second surface comprising thermo diodic characteristics between said first surface and said second surface, and further comprising:
a substrate with a metallic surface;
a first metallic layer comprising a different metal than the metallic surface of the substrate, said first metallic layer in electrical contact with the metallic surface of the substrate;
a conductive ionic layer in electrical contact with the first metallic layer; and
a second metallic layer, said second metallic layer separated from the conductive ionic layer by a gap which thermally insulates the second metallic layer from the conductive ionic layer.

3. The device of claim 2 wherein the gap comprises a low pressure ambient sufficient to provide thermal insulation between the second metallic layer and the conductive ionic layer.

4. The device of claim 2 wherein a DC current can be applied across the first surface and the second surface to transfer thermal energy through the device.

5. The device of claim 2 wherein a temperature differential can be applied across the first surface and the second surface to cause a voltage to be generated.

6. The device of claim 1 wherein: the first metallic layer and second metallic layer comprise silver, the conductive ionic layer comprises silver sulfide; and the third metallic layer comprises gold.

7. The device of claim 2 wherein: the first metallic layer comprises silver, the conductive ionic layer comprises silver sulfide; and the second metallic layer comprises gold.

8. The device of claim 1 wherein the conductive ionic layer comprises a first surface in electrical and thermal contact with the first metallic layer and a second surface, wherein the second surface comprises an atomically textured area.

9. The device of claim 1 wherein the conductive ionic layer comprises a first surface in electrical and thermal contact with the first metallic layer and a second surface in electrical and thermal contact with the second metallic layer and each of the first surface and the second surface comprises an atomically smooth area.

10. The device of claim 1 wherein the first metallic layer and second metallic layer comprise silver; the conductive ionic layer comprises silver sulfide and the third metallic layer primarily comprises gold and the device additionally comprises at least one intervening gap layer between the gold and the metallic substrate surface.

11. The device of claim 1 wherein first metallic layer comprises silver; the conductive ionic layer comprises silver sulfide, the second metallic layer is removed to form a gap and the third metallic layer primarily comprises gold.

12. The devices of claims 10 additionally comprising a layer of spin on glass.

13. A device with a first surface and a second surface comprising thermo diodic characteristics between said first surface and said second surface, and further comprising:
a substrate with a metallic surface;
a first layer of low work function metal comprising a different metal than the metallic surface of the substrate, said first low work function metal layer in electrical contact with the metallic surface of the substrate;
a sacrificial layer of selectively etchable material in physical contact with the first low work function metal layer;
a second low work function metal layer, said second low work function metal layer in contact with the second layer of low work function metal; and
a third metallic layer in contact with the second low work function metal layer.

14. The device of claim 13 additionally comprising a contact via formed through the second low work function metal.

15. The device of claim 14 wherein the a sacrificial layer of selectively etchable material is replaced by a gap which thermally insulates the first low work function layer from the second low work function layer.

16. The device of claim 15 wherein the contact via is sealed.

17. A thermo transfer device with a first surface and a second surface wherein the first surface comprises multiple areas and the application of a direct current voltage can be applied to individually cause the transfer of thermal energy from the specified area of the first surface to the second surface.

18. The thermo transfer device of claim 17 wherein at least one of the multiple areas comprising the first surface corresponds with an area on an adjacent article and the direct current voltage can be applied to the at least one multiple area to transfer thermal energy away from the area on the adjacent article.

19. The thermo transfer device of claim 18 wherein a temperature threshold has been designated for the area on the adjacent article and the direct current voltage is applied based upon the temperature of the area on the adjacent article relative to the temperature threshold.

20. The thermo transfer device of claim 18 wherein the thermo transfer device and the adjacent article comprise a composite discrete device.

21. A device with a first surface and a second surface comprising thermo diodic characteristics between said first surface and said second surface, and further comprising:
a substrate with a metallic surface;
a first metallic layer comprising an atomically textured metal, said first metallic layer in physical contact with the metallic surface of the substrate;
a conductive ionic layer, said conductive ionic layer separated from the first metallic layer by a gap which thermally insulates the first metallic layer from the conductive ionic layer; and
a second metallic layer, said second metallic layer in physical contact with the conductive ionic layer.

22. The device of claim 21 wherein the textured metal comprises spikes generated via ionic migration through the ionic conductor induced by an electrical current.

23. The device of claim 21 furthered processed with etching through a contact via.

24. The device of claim 21 additionally comprising a sealant which seals the gap in a vacuum state sufficiently void of molecules to reduce thermal parasitics between the second metallic layer and the conductive ionic layer.

25. A device with a first surface and a second surface comprising thermal diodic characteristics between said first surface and said second surface, and further comprising:
two or more stacked portions wherein each portion comprises thermal diodic characteristics and each portion further comprises:
a substrate with a metallic surface;
a first metallic layer comprising an atomically textured metal, said first metallic layer in physical contact with the metallic surface of the substrate;
a conductive ionic layer, said conductive ionic layer separated from the first metallic layer by a gap which thermally insulates the first metallic layer from the conductive ionic layer; and
a second metallic layer, said second metallic layer in physical contact with the conductive ionic layer.

26. The device of claim 25 wherein an electrical current can be applied between the substrate and the second metallic layer of any respective portion to cause a transfer of thermal energy between the substrate and the second metallic surface.

27. A method of forming a device comprising thermal diodic characteristics between a first surface and a second surface, the method comprising:
a substrate with a metallic surface;
applying a first metallic layer into electrical and thermal contact with a metallic surface of a substrate, the first metallic layer comprising a different metal than the metallic surface of the substrate;
applying a conductive ionic layer into electrical contact with the first metallic layer;
applying a second metallic layer into electrical contact with the conductive ionic layer;
applying a third metallic layer into electrical contact with the second metallic layer, whereby the third metallic layer comprises a metal different than the second metallic layer;
removing portion of one of: the first metallic layer and the second metallic layer, to form a gap between the ionic conductive layer and metallic layer from which the portion is removed.

28. The method of claim 27 wherein the step of removing the portion of at least one of the first metallic layer and the second metallic layer comprises application of an electrical current between the substrate the third metallic layer.

29. The method of claim 27 wherein the step of removing the portion of at least one of the first metallic layer and the second metallic layer comprises etching the portion of the layer removed.

30. The method of claim 29 additionally comprising the steps of:
etching a via through one or more of: the third metallic layer, the second metallic layer and the ionic conductor layer; and
selectively etching one of the first metallic layer and the second metallic layer.

31. The method of claim 30 additionally comprising the steps of:
etching one or more channels through all of the layers except the substrate; and
applying a first layer of insulator material into the one or more channels, wherein said insulator seals said layers and provides physical support to one or more said layers.

32. The method of claim 31 additionally comprising the steps of:
etching the first layer of insulator; and
applying a second layer of insulator material comprising a material that is different from the first layer of insulator material.

33. The method of claim 32 wherein: the first metallic layer and second metallic layer comprise silver, the conductive ionic layer comprises silver sulfide; and the third metallic layer comprises gold.

34. The method of claim 32 wherein: the first metallic layer comprises silver, the conductive ionic layer comprises silver sulfide; and the second metallic layer comprises gold.

35. The method of claim 32 wherein the conductive ionic layer comprises a first surface in electrical and thermal contact with the first metallic layer and a second surface, wherein the second surface comprises an atomically textured area.

36. The method of claim 32 wherein the conductive ionic layer comprises a first surface in electrical and thermal contact with the second metallic layer and a second surface exposed to the gap and each of the first surface and wherein the second surface comprises an atomically smooth area.

37. The method of claim 32 wherein one or more of the first insulator material and the second insulator material comprises spin on glass.

38. The method of claims 37 additionally comprising the step of applying a temperature differential across the first surface and the second surface to cause a voltage to be generated.

39. A method of forming a device comprising thermal diodic characteristics, the method comprising:
applying a first layer of a low work function metal into electrical and thermal contact with a metallic substrate surface;
applying a sacrificial layer of selectively etchable metal on top of the first layer of low work function metal;
applying a second layer of low work function metal on top of the TiN;
applying a layer of Au on top of the second layer of low work function metal;
etching one or more channels through the layer of Au, the second layer of low work function metal, the TiN and the first layer of low work function metal;
applying at least one layer of insulator material into each of the channels;
etching an access via through the Au and the second layer of low work function metal;
selectively etching out at least a portion of the layer of TiN until all solid state electrical connection has been removed between the first layer of low work function metal and the second layer of low work function metal; and
sealing the access via with an insulator.

40. The method of claim 39 wherein the selective etch creates an atomically textured surface of remaining TiN.

41. A device comprising a thermoelectric portion in thermal contact with a thermal diode portion capable of transferring thermal energy between the thermoelectric portion and the thermal diode portion in a predetermined direction.

42. A device comprising two or more alternating thermal diodic portions and thermoelectric portions.
